(19) United States
(12) Patent Application Publication
(10) Pub. No.: US 2023/0312943 A1
(43) Pub. Date: Oct. 5, 2023

(54) PHOSPHOR COATING MATERIAL, COATING FILM, PHOSPHOR BOARD, AND ILLUMINATION DEVICE

(71) Applicant: DENKA COMPANY LIMITED, Tokyo (JP)

(72) Inventor: Masahiro KONISHI, Tokyo (JP)

(73) Assignee: DENKA COMPANY LIMITED, Tokyo (JP)

(21) Appl. No.: 18/020,098

(22) PCT Filed: Jul. 30, 2021
(86) PCT No.: PCT/JP2021/028400

§ 371 Date: Feb. 7, 2023

(30) Foreign Application Priority Data
Aug. 7, 2020 (JP) 2020-134392

(51) Int. Cl. C09D 7/61; C09D 5/22; C09D 183/06; C09D 7/20; C08J 7/04; C09K 11/64; H01L 33/50

(52) U.S. Cl. CPC C09D 7/61; C09D 5/22; C09D 183/06; C09D 7/20; C08J 7/0427; C09K 11/64; H01L 33/502; C08J 2383/06

(57) ABSTRACT

A phosphor coating material containing phosphor particles and a curable resin component. A viscosity of the phosphor coating material, measured at 25° C. and a rotation speed of 20 rpm using a B-type viscometer, is equal to or more than 60 dPa·s and equal to or less than 450 dPa·s.

### TECHNICAL FIELD

The present invention relates to a phosphor coating material, a coating film, a phosphor board, and an illumination device.

### BACKGROUND ART

Various developments have been conducted for an illumination device using a light emitting device (LED). Not only the development of LED itself, but also the development of a mounting substrate with LED has been known.

For example, in Example 2 of Patent Document 1, it is disclosed that, in a case where (i) a glass binder coating material containing a 30 vol % phosphor substance is applied to a surface of a glass substrate to form a phosphor layer having a thickness of 200 μm, (ii) a plurality of CSPs are bonded onto the glass substrate to obtain an LED illumination mounting substrate, and (iii) the mounting substrate is energized, problems of glare and multiple shadows are reduced even though light is emitted from the plurality of CSPs.

(CSP is an abbreviation for Chip Scale Package or Chip Size Package, which means a package-less configuration consisting only of an LED chip and a fluorescent resin, in which the LED chip is wrapped in the fluorescent resin)

### RELATED DOCUMENT

### Patent Document

[Patent Document 1] Pamphlet of International Publication No. WO2019/093339

### SUMMARY OF THE INVENTION

### Technical Problem

In Example 2 of Patent Document 1, the phosphor layer having a thickness of 200 μm is formed on the glass substrate using the “glass binder coating material” containing the phosphor substance. However, in order to fully cure the glass binder coating material, a sintering step at a high temperature is usually required, so that there is room for improvement in terms of simplicity of providing the phosphor layer. In addition, a housing or substrate to which the glass binder coating material is applied also limitations such as heat resistance and optimization of expansion coefficient.

The present invention has been made in view of such circumstances. An object of the present invention is to provide a material with which a phosphor layer can be easily formed.

### Solution to Problem

As a result of intensive studies, the present inventors have completed the invention provided below, thereby solving the above-described problems.

According to the present invention, there is provided a phosphor coating material containing phosphor particles and a curable resin component, in which a viscosity measured at 25° C. and a rotation speed of 20 rpm using a B-type viscometer is equal to or more than 60 dPa·s and equal to or less than 450 dPa·s.

In addition, according to the present invention, there is provided a coating film formed from the above-described phosphor coating material.

In addition, according to the present invention, there is provided a phosphor board including the above-described coating film.

In addition, according to the present invention, there is provided an illumination device including an insulating substrate, a coating film provided on one surface of the insulating substrate by the above-described phosphor coating material according, and a light-emitting element installed on a surface of the coating film opposite to the insulating substrate.

### Advantageous Effects of Invention

By using the phosphor coating material according to the aspect of the present invention, it is possible to easily provide a phosphor layer.

### BRIEF DESCRIPTION OF THE DRAWINGS

FIG. 1 is a schematic cross-sectional view of an illumination device.

FIGS. 2A and 2B are diagrams for describing an LED chip including no reflector and an LED chip including a reflector.

### DESCRIPTION OF EMBODIMENTS

Hereinafter, embodiments of the present invention will be described in detail with reference to the drawings.

In all drawings, the same components are designated by the same reference numerals, and description thereof will not be repeated.

All drawings are for illustration purposes only. The shape and dimensional ratio of each member in the drawings do not necessarily correspond to the actual article.

In the present specification, the notation “(meth)acrylic” represents a concept which includes both acrylic and methacrylic. The same applies to similar notations such as “(meth)acrylate”.

In the present specification, the term “phosphor particles” may mean “phosphor powder” which is an aggregate of the phosphor particles, depending on the context. For example, the “median diameter D₅) of the phosphor particles”, which will be described later, is a value obtained based on a particle size distribution of the phosphor powder which is an aggregate of the phosphor particles.

<Phosphor Coating Material>

The phosphor coating material according to the present embodiment contains phosphor particles and a curable resin component.

A viscosity of the phosphor coating material according to the present embodiment, measured under the conditions of 25° C. and a rotation speed of 20 rpm using a B-type viscometer, is equal to or more than 60 dPa·s and equal to or less than 450 dPa·s.

A content of the phosphor particles in all non-volatile components is equal to or more than 25 vol % and equal to or less than 60 vol %.

The phosphor coating material according to the present embodiment contains a curable “resin component” instead of a glass binder. Therefore, by using the phosphor coating material according to the present embodiment, a phosphor layer can be provided relatively easily without requiring sintering at a high temperature.

The “without requiring sintering at a high temperature” means that phosphor substances which can be used are not limited. Specifically, in a case of obtaining a cured film with the glass binder, baking at a high temperature of approximately 600° C. is required. In a case where such a high temperature is required, it is necessary to select a phosphor substance which can withstand high temperature, so that phosphor substances which can be used are limited. In addition, peeling is likely to occur during cooling from the high temperature. However, by preparing a phosphor coating material using the curable resin component, it is possible to form a phosphor layer which does not easily peel off without requiring a high temperature of approximately 600° C.

The “without requiring sintering at a high temperature” also leads to advantage that there are few restrictions such as heat resistance and optimization of expansion coefficient of a housing or substrate on which the coating material is applied or printed.

In addition, by using the curable resin component, it is easy to form an appropriately thin phosphor layer by coating or printing. This is particularly effective in a case where the content of the phosphor particles in the phosphor coating material is high.

In particular, in the present embodiment, since the viscosity is equal to or more than 60 dPa·s and equal to or less than 450 dPa·s, for example, a screen printing method suitable for mass production can be used to form a phosphor layer (coating film including phosphor particles) with an appropriate thickness and little unevenness on the substrate.

In the present embodiment, by using an appropriate material in an appropriate amount, the phosphor coating material having a viscosity of equal to or more than 60 dPa·s and equal to or less than 450 dPa·s can be obtained. Specifically, by using an appropriate amount of phosphor particles having an appropriate particle size distribution, using an appropriate amount of an appropriate fluidity modifier, and using an appropriate amount of an appropriate solvent, the phosphor coating material according to the present embodiment can be manufactured.

Hereinafter, components and physical properties of the phosphor coating material according to the present embodiment will be described.

(Phosphor Particles)

The phosphor coating material according to the present embodiment contains phosphor particles. It is sufficient that the phosphor particles emit fluorescent light by the light emitted from the light-emitting element. Depending on the desired hue, color temperature, and the like, only one type of specific phosphor particles may be used, or two or more phosphor particles may be used in combination.

Examples of the phosphor particles include one or two or more kinds selected from the group consisting of a CASN-based phosphor substance, an SCASN-based phosphor substance, a La₃Si₆N₁₁-based phosphor substance, a Sr₂Si₅N₈-based phosphor substance, a Ba₂Si₅N₈-based phosphor substance, an α-sialon-based phosphor substance, a β-sialon-based phosphor substance, a LuAG-based phosphor substance, and a YAG-based phosphor substance. These phosphor substances usually contain activating elements such as Eu and Ce.

The CASN-based phosphor substance (a kind of nitride phosphor substance) preferably contains Eu. The CASN-based phosphor substance is represented by, for example, a formula CaAlSiN₃:Eu²⁺, and refers to a red phosphor substance which uses Eu²⁺ as an activator and has crystals including alkaline earth silicon nitride as a matrix.

In the present specification, the definition of CASN-based phosphor substance containing Eu excludes an SCASN-based phosphor substance containing Eu.

The SCASN-based phosphor substance (a kind of nitride phosphor substance) preferably contains Eu. The SCASN-based phosphor substance is represented by, for example, a formula (Sr, Ca) AlSiN₃:Eu²⁺, and refers to a red phosphor substance which uses Eu²⁺ as an augmenting agent and has crystals including alkaline earth silicon nitride as a matrix.

The La₃Si_{F}N₁₁-based phosphor substance is specifically a La₃Si₆N₁₁:Ce phosphor substance and the like. This typically converts a wavelength of blue light from a blue LED to a wavelength of yellow light.

The Sr₂Si₅N₈-based phosphor substance is specifically a Sr₂Si₅N₈:Eu²⁺ phosphor substance, a Sr₂Si₅N₈:Ce³⁺ phosphor substance, and the like. These typically convert a wavelength of blue light from a blue LED to wavelengths of yellow to red light.

The Ba₂Si₅N₈-based phosphor substance is specifically a Ba₂Si₅N₈:Eu phosphor substance and the like. This typically converts a wavelength of blue light from a blue LED to wavelengths of orange to red light.

The α-sialon-based phosphor substance preferably contains Eu. The α-sialon containing Eu is represented by, for example, a general formula MₓEu_{y}Si₁₂₋₍ₘ₊ₙ₎Al₍ₘ₊ₙ₎OₙN₁₆₋ₙ. In the general formula, M is one or more elements selected from the group consisting of Li, Mg, Ca, Y, and lanthanide elements (excluding La and Ce), including at least Ca, and in a case where a valence of M is defined as a, ax+2y=m, x satisfies 0<x≤1.5, 0.3≤m<4.5, and 0<n<2.25.

The β-sialon-based phosphor substance preferably contains Eu. The β-sialon containing Eu is represented by, for example, a general formula Si_{6-z}Al_{z}O_{z}N_{8-z}:Eu²⁺ (0<Z≤4.2), and is a phosphor substance including R-sialon in which Eu²⁺ is solid-dissolved. In the general formula, the Z value and the content of europium are not particularly limited. The Z value is, for example, more than 0 and equal to or less than 4.2, and from the viewpoint of further improving emission intensity of the β-sialon, it is preferably equal to or more than 0.005 and equal to or less than 1.0. In addition, the content of europium is preferably equal to or more than 0.1% by mass and equal to or less than 2.0% by mass.

The LuAG-based phosphor substance generally means a lutetium-aluminum garnet crystal. In consideration of application to the illumination device, LuAG is preferably a LuAG:Ce phosphor substance. More specifically, LuAG can be represented by a composition formula of Lu₃Al₅O₁₂:Ce, but the composition of LuAG does not necessarily follow stoichiometry.

The YAG-based phosphor substance generally means an yttrium-aluminum garnet crystal. In consideration of application to the illumination device, the YAG-based phosphor substance is preferably Ce-activated. More specifically, the YAG-based phosphor substance can be represented by a composition formula of Y₃Al₅O₁₂:Ce, but the composition of the YAG-based phosphor substance does not necessarily follow stoichiometry.

A commercially available product may be used as the phosphor particles. Examples of commercially available phosphor particles include ALONBRIGHT (registered trademark) manufactured by Denka Company Limited. In addition, the phosphor particles are commercially available from Mitsubishi Chemical Corporation and the like.

A median diameter D₅₀ of the phosphor particles is preferably equal to or more than 1 μm and equal to or less than 20 μm, more preferably equal to or more than 5 μm and equal to or less than 15 μm. By appropriately adjusting the median diameter D₅₀, for example, fluidity as a phosphor coating material is adjusted, and it is easier to form a thin and uniform coating film.

In a particle size distribution curve of the phosphor particles, it is preferable that two or more maxima are observed. Specifically, it is preferable that the maxima are observed in both a region of a particle size of equal to or more than 1 μm and equal to or less than 6 μm and a region of a particle size of equal to or more than 10 μm and equal to or less than 25 μm. The presence of two or more maxima means that the phosphor particles contain both large particles and small particles. Since the small particles enter “gap” between the large particles, it is easier to increase the content of the phosphor particles than a case where only the large particles are used. In addition, even in a case where the content of the phosphor particles is increased, it is easy to maintain various physical properties as a coating material. Furthermore, in a case of being formed into a coating film, the light emitted from the light-emitting element is more difficult to transmit.

The median diameter D₅₀ and the particle size distribution curve of the phosphor particles can be adjusted by devising a method for preparing the phosphor particles, appropriately pulverizing the phosphor particles, appropriately mixing two or more phosphor particles having different particle sizes, and the like.

The particle size distribution curve of the phosphor particles can be measured by a laser diffraction and scattering particle size distribution analyzer, after dispersing raw phosphor particles in a dispersion medium using an ultrasonic homogenizer. Thereafter, the median diameter D₅₀ can be obtained from the obtained particle size distribution curve. The details of the dispersion processing and the measuring device can be referred to Examples described later.

Just to be sure, in the present specification, the median diameter D₅₀ and the particle size distribution curve are measured on a volume basis.

The phosphor coating material according to the present embodiment may contain only one type of phosphor particles, or may contain two or more types thereof.

The content of the phosphor particles in all non-volatile components of the phosphor coating material is, for example, equal to or more than 25 vol % and equal to or less than 60 vol %. The content is preferably equal to or more than 30 vol % and equal to or less than 60 vol %, more preferably equal to or more than 35 vol % and equal to or less than 60 vol %, and still more preferably equal to or more than 40 vol % and equal to or less than 50 vol %.

By setting the content of the phosphor particles in all non-volatile components of the phosphor coating material to be equal to or more than 25 vol %, for example, the light emitted from the light-emitting element can be sufficiently converted into the fluorescent light.

In addition, examples of other merits include further improvement in coating or printing suitability. In a case where the content of the phosphor particles in the phosphor coating material is moderately high, the phosphor coating material is difficult to flow moderately, and as a result, it is easy to form a phosphor layer with a moderate film thickness.

By setting the content of the phosphor particles in all non-volatile components of the phosphor coating material to be equal to or more than 25 vol %, there is also merit that cracks are less likely to occur in the phosphor layer. Based on general knowledge, it is considered that one of causes of the crack generation is a difference in coefficient of thermal expansion between the phosphor layer and a substrate on which the phosphor layer is provided. By setting the content of the phosphor particles in all non-volatile components of the phosphor coating material to be equal to or more than 25 vol %, the curable resin component is relatively reduced. Therefore, the difference between the coefficient of thermal expansion of the phosphor layer and the coefficient of thermal expansion of the substrate on which the phosphor layer is provided is reduced. As a result, cracks are less likely to occur in the phosphor layer.

Since the content of the phosphor particles in all non-volatile components of the phosphor coating material is high, for example, even in a case where the phosphor layer is thin, the light emitted from the light-emitting element can be sufficiently converted into the fluorescent light, or color temperature of the light emitted from the light-emitting element can be greatly converted.

On the other hand, from the viewpoint of preventing the phosphor particles from falling off from the formed phosphor layer, the content of the phosphor particles in all non-volatile components of the phosphor coating material is preferably equal to or less than 60 vol %.

(Curable Resin Component)

The phosphor coating material according to the present embodiment contains a curable resin component.

In the present specification, the “curable resin component” includes not only (1) a resin (polymer) component which has property of being cured by action of heat, light, and the like, but also (2) a component which is a monomer or an oligomer before coating film formation, but can form a resin (polymer) by increasing a molecular weight by the action of heat, light, and the like after coating film formation.

In connection with the above, in the present specification, a polymerization initiator, a curing agent, and the like are also included in the “curable resin component”, in addition to the polymer, and the monomer or the oligomer.

In a case where the curable resin component includes the resin, or the monomer or the oligomer, these are usually an organic substance. That is, the curable resin component typically includes an organic resin, an organic monomer, or an organic oligomer.

The curable resin component preferably includes a thermosetting resin component. As a result, an illumination device with high durability can be manufactured. Needless to say, depending on the purpose and application, the curable resin component may include a thermoplastic resin.

The curable resin component preferably includes one or two or more kinds selected from the group consisting of a silicone resin and a (meth)acrylate monomer. Among these, from the viewpoint of heat resistance and durability, a silicone resin (a resin having a siloxane bond as a main skeleton) is preferable.

It is preferable that the curable resin component includes a silicone resin having a phenyl group and/or a methyl group. Such a silicone resin is preferable from the viewpoint of compatibility with other components, solvent solubility, coatability, heat resistance, durability, and the like. A ratio of phenyl group:methyl group in the resin is, for example, approximately 0.3:1 to 1.5:1.

The curable resin component can contain a reactive group. As a result, the curable resin component itself can be cured.

As an example, the curable resin component preferably includes a silicone resin having a silanol group (—Si—OH). As a result, a condensation reaction of silanol groups occurs during the coating film formation, and a cured coating film is obtained. A silanol content (OH % by weight) of the silicone resin having a silanol group (—Si—OH) is, for example, equal to or more than 0.1% by mass and equal to or less than 5% by mass.

As another example, the curable resin component may be a compound (addition reaction type) that cures through a hydrosilylation reaction between a vinyl group-containing polymer and a Si—H group-containing silicone polymer.

A weight-average molecular weight of the resin included in the curable resin component is not particularly limited. Any resin having a weight-average molecular weight can be included as long as it can be used as a coating material for forming a coating film.

As an example, the weight-average molecular weight of the resin included in the curable resin component is generally equal to or more than 1,000 and equal to or less than 1,000, 000, preferably equal to or more than 1,000 and equal to or less than 500,000.

In a case where a commercially available product is used as the resin included in the curable resin component, catalog data can be used as the weight-average molecular weight of the resin. In a case where the weight-average molecular weight is unknown from a catalog or the like, the weight-average molecular weight can be determined by, for example, gel permeation chromatography (GPC) measurement using polyethylene as a standard substance.

A commercially available product may be used as the resin included in the curable resin component.

A commercially available product of the silicone resin is available, for example, from Dow Toray Co., Ltd., Shin-Etsu Chemical Co., Ltd., and the like. Examples thereof include RSN-0409, RSN-0431, RSN-0804, RSN-0805, RSN-0806, RSN-0808, RSN-0840, and the like (manufactured by Dow Toray Co., Ltd.); and KF-8010, X-22-161A, KF-105, X-22-163A, X-22-169AS, KF-6001, KF-2200, X-22-164A, X-22-162C, X-22-167C, X-22-173BX, and the like (manufactured by Shin-Etsu Chemical Co., Ltd.).

As described above, the curable resin component may include a monomer or an oligomer rather than the resin.

For example, the curable resin component preferably includes a (meth)acrylate monomer. The (meth)acrylate monomer may be monofunctional or polyfunctional. The (meth)acrylate monomer preferably has equal to or more than 2 and equal to or less than 6 of (meth)acrylic structures in one molecule.

The curable resin component preferably includes a polymerization initiator together with the monomer or the oligomer.

For example, in a case where the curable resin component includes a (meth)acrylate monomer, it is preferably to use a radical polymerization initiator in combination. The radical polymerization initiator generates radicals by heat or actinic rays.

The curable resin component may be any component known in the field of coating material, in addition to the silicone resin as described above, or the combination of the (meth)acrylate monomer and the polymerization initiator. The curable resin component may be, for example, (i) a urethane-based component including a polyol and a polyisocyanate, (ii) an epoxy-based component, or the like.

Examples of the (i) polyol include (meth)acrylic polyol, polyester polyol, polyether polyol, epoxy polyol, polyolefin-based polyol, fluorine-containing polyol, polycaprolactone polyol, polycaprolactam polyol, and polycarbonate polyol.

Preferred examples of the (i) polyisocyanate include difunctional to hexafunctional polyisocyanate, and more preferred examples thereof include difunctional to tetrafunctional polyisocyanate. Specific examples thereof include aliphatic diisocyanate, cycloaliphatic diisocyanate, isocyanurate and biuret-type adducts which are a multimer of an isocyanate compound, and compounds obtained by adding an isocyanate compound to a polyhydric alcohol or a low-molecular-weight polyester resin. Biuret-type, isocyanurate-type, adduct-type, and allophanate-type polyisocyanates are also known. Any of these can be used.

The (i) polyisocyanate may be a so-called blocked isocyanate. In other words, a part or all of isocyanate groups of the polyisocyanate may be in a form of blocked isocyanate groups blocked by a protective group. For example, an isocyanate group is blocked by an active hydrogen compound such as an alcohol-based compound, a phenol-based compound, a lactam-based compound, an oxime-based compound, and an active methylene-based compound to form a blocked isocyanate group.

Examples of a commercially available product of the polyisocyanate include Duranate (trade name) series manufactured by Asahi Kasei Corporation, TAKANATE (trade name) series manufactured by Mitsui Chemicals, Inc., and Desmodur (trade name) series manufactured by Sumitomo Bayer Urethane Co., Ltd.

The (ii) epoxy-based curable resin component generally includes an epoxy resin and its curing agent.

Examples of the epoxy resin include a bisphenol A-type epoxy resin, a halogenated bisphenol A-type epoxy resin, a novolac-type epoxy resin, a polyglycol-type epoxy resin, a bisphenol F-type epoxy resin, an epoxidized oil, 1,6-hexanediol diglycidyl ether, and neopentyl glycol diglycidyl ether.

Examples of the curing agent include polyamines such as a polyvalent amine, an amine adduct, and a polyamide, and acid anhydrides.

The phosphor coating material according to the present embodiment may contain only one type of curable resin component, or may contain two or more types thereof.

An amount of the curable resin component in the phosphor coating material according to the present embodiment in all non-volatile components is preferably equal to or more than 40 vol % and equal to or less than 65 vol %, and more preferably equal to or more than 45 vol % and equal to or less than 60 vol %.

(Fluidity Modifier)

The phosphor coating material according to the present embodiment preferably contains a fluidity modifier. As a result, in some cases, it is possible to adjust viscosity, adjust fluidity characteristics (for example, thixotropic properties) of the coating material, and adjust coatability.

As the fluidity modifier, silica particles such as hydrophobic silica and hydrophilic silica, aluminum oxide, and the like can be used. In particular, fumed silica is preferably used.

Examples of a commercially available fluidity modifier include AEROSIL 130, AEROSIL 200, AEROSIL 300, AEROSIL R-9712, AEROSIL R-812, AEROSIL R-812S, and Aluminum Oxide C (manufactured by NIPPON AEROSIL CO., LTD.; AEROSIL is registered trademark), and Carplex FPS-1 (manufactured by DSL, trade name).

In a case where the phosphor coating material according to the present embodiment contains a fluidity modifier, the phosphor coating material according to the present embodiment may contain only one type of fluidity modifier, or may contain two or more types of fluidity modifiers.

In a case where the phosphor coating material according to the present embodiment contains a fluidity modifier, an amount thereof in all non-volatile components is, for example, equal to or less than 10 vol %, preferably equal to or more than 1 vol % and equal to or less than 5 vol %. On a mass basis rather than a volume basis, the amount of the fluidity modifier in all non-volatile components is, for example, equal to or less than 5 mass %, preferably equal to or more than 0.1 mass % and equal to or less than 5 mass %.

(Solvent)

The phosphor coating material according to the present embodiment preferably contains a solvent. As a result, it is possible to obtain a phosphor coating material with good coatability. The solvent includes water and/or an organic solvent.

Examples of the organic solvent include a hydrocarbon-based solvent, a ketone-based solvent, an ester-based solvent, an alcohol-based solvent, an amide-based solvent, and an ether-based solvent.

Preferred examples of the organic solvent include an alcohol-based solvent. Specific examples thereof include methanol, ethanol, n-propanol, 2-propanol, n-butanol, 2-butanol, and t-butanol. In addition, preferred examples thereof also include ether bond-containing alcohols such as butyl carbitol (diethylene glycol monobutyl ether) and ethyl carbitol (diethylene glycol monoethyl ether). In particular, in a case where the silicone resin is used as the resin, these are preferable in that the silicone resin can be well dissolved and dispersed to prepare a phosphor coating material with good coatability.

In addition, the solvent preferably includes an aromatic hydrocarbon solvent. In particular, in a case where the silicone resin is used, by using the aromatic hydrocarbon solvent in combination, it is easy to prepare a phosphor coating material having a good balance of properties. Examples of the aromatic hydrocarbon solvent include toluene and xylene.

In a case of using a solvent, only one type of solvent may be used, or two or more types of solvents may be used in combination. For example, the alcohol-based solvent and the aromatic hydrocarbon solvent described above may be used in combination. In a case of using solvents in combination, from the viewpoint of sufficiently obtaining effect of combined use, each solvent is preferably present in an amount of at least 1% by mass of the total amount of the solvents.

In a case where the phosphor coating material according to the present embodiment contains a solvent, it is preferable that the solvent is contained in such an amount that the non-volatile component concentration is equal to or less than 90% by mass. However, the non-volatile component concentration is not limited to this, and the amount may be appropriately adjusted as long as the coating film can be formed.

(Other Components)

The phosphor coating material according to the present embodiment may contain a component other than the above-described components. Examples of other components include an antirust pigment, an extender pigment, a surface conditioner, a wax, a defoaming agent, a dispersant, an JV absorber, a light stabilizer, an antioxidant, a leveling agent, an anti-wrinkling agent, a plasticizer, and a charge control agent.

(Viscosity)

As described above, the viscosity of the phosphor coating material according to the present embodiment, measured at 25° C. and a rotation speed of 20 rpm using a B-type viscometer, is equal to or more than 60 dPa·s and equal to or less than 450 dPa·s. The viscosity is preferably equal to or more than 80 dPs·s and equal to or less than 350 dPa·s, and more preferably equal to or more than 90 dPs·s and equal to or less than 320 dPa·s. By setting the viscosity to such a value, in particular, a screen printing method can be used to form a phosphor layer with an appropriate thickness.

(Form of Coating Material)

The phosphor coating material according to the present embodiment may be of a one-liquid type or a multi-liquid type of two or more liquids. Specifically, the resin composition for forming a film according to the present embodiment can be supplied as a one-liquid type composition in which all of the necessary components are uniformly mixed or dispersed. In addition, the resin composition for forming a film according to the present embodiment may be supplied as a two-liquid type (two-liquid kit) of a liquid A including some of the components and a liquid B including the remaining components.

From the viewpoint of storage stability before coating, in some cases, it is preferable to use a multi-liquid type phosphor coating material.

In a case where the phosphor coating material according to the present embodiment is of a multi-liquid type, immediately before forming the coating film, each liquid is uniformly mixed to obtain a coating material for coating. A viscosity of the coating material for coating is set to equal to or more than 60 dPa·s and equal to or less than 450 dPa·s.

<Coating Film, Phosphor Board, and Illumination Device>

A coating film including the phosphor particles can be formed using the above-described phosphor coating material.

In addition, a phosphor board which includes the coating film including the phosphor particles can be manufactured using the above-described phosphor coating material.

Furthermore, using the above-described phosphor coating material, an illumination device, which includes an insulating substrate, an insulating substrate, a coating film provided on one surface of the insulating substrate by the above-described phosphor coating material according, and a light-emitting element (an LED element or the like) installed on a surface of the coating film opposite to the insulating substrate, can be manufactured.

Hereinafter, the coating film, the phosphor board, and the illumination device will be described with reference to a configuration example of the illumination device.

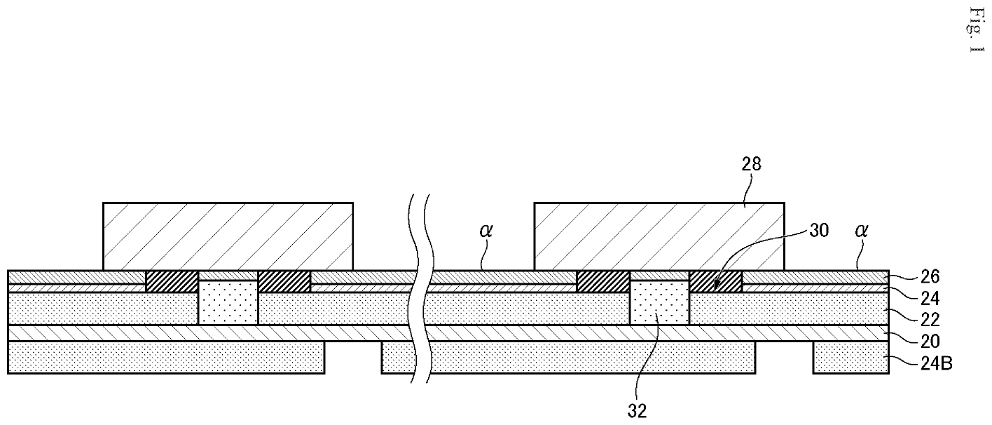

FIG. 1 is a schematic cross-sectional view of the illumination device.

In the illumination device of FIG. 1, a phosphor coating film 26 is provided on one surface of an insulating substrate 20. A first copper foil 22 and a white layer 24 are provided between the insulating substrate 20 and the phosphor coating film 26 in order from the insulating substrate 20 side. A part of the first copper foil 22 is removed by etching and functions as a copper circuit (copper wiring).

A surface-mounted LED element 28 (light-emitting element) is installed on a surface of the phosphor coating film 26 opposite to the insulating substrate 20. The surface-mounted LED element 28 is electrically connected to the first copper foil 22 by a solder 30 which penetrates the white layer 24 and the phosphor coating film 26. Electricity is supplied to the surface-mounted LED element 28 by the first copper foil 22 and the solder 30, and the surface-mounted LED element 28 emits light.

From the viewpoint of increasing fluorescence efficiency of the phosphor coating material, it is preferable that a white layer 32 (more specifically, a white resin layer 32) is provided below the surface-mounted LED element 28. As a result, it is possible to suppress the escape (transmission) of light. In addition, at least a part of the incident light from the phosphor coating film 26 is reflected at an interface between the white layer 32 and the phosphor coating film 26.

The illumination device of FIG. 1 can include a plurality of the surface-mounted LED elements 28.

A second copper foil 22B can be provided on the other surface of the insulating substrate 20 (a surface opposite to the side on which the phosphor coating film 26 is provided). Since the first copper foil 22 is provided on one surface of the insulating substrate 20 and the second copper foil 22B is provided on the other surface of the insulating substrate 20, forces are balanced on both surfaces of the insulating substrate 20, and for example, warping is suppressed.

A material of the insulating substrate 20 is not particularly limited as long as it can be used for a printed wiring board (PWB). For example, a polyimide resin, a silicone resin, a (meth)acrylic resin, a urea resin, an epoxy resin, a fluorine resin, glass, and metal (aluminum, copper, iron, stainless steel, and the like) can be used. From the viewpoint of heat resistance, a polyimide resin, a silicone resin, glass, or metal (so-called “metal substrate” in which aluminum or copper is used as a base metal and an insulating layer is provided) can be preferably used. It is also preferable to use a material commercially available under the name of “Bonding sheet” or the like.

A thickness of the insulating substrate 20 is not particularly limited as long as it can be used for illumination fixtures. For example, the thickness thereof is equal to or more than 50 μm and equal to or less than 1000 μm, specifically equal to or more than 50 μm and equal to or less than 500 μm.

The white layer 24 and the white layer 32 can be provided using, for example, a white coating material. Composition and properties of the white coating material are not particularly limited as long as the white layer 24 can be formed. Examples thereof include a coating material composition using a white pigment instead of the phosphor particles in the above-described coating material composition. The coating method can be the same as that of the phosphor coating film 26 described below.

Examples of the white pigment include known pigments such as titanium oxide. From the viewpoint of stability, an inorganic pigment is preferable.

For example, a thickness of the white layer 24 is equal to or more than 10 μm and equal to or less than 500 μm, specifically equal to or more than 20 μm and equal to or less than 400 μm.

The phosphor coating film 26 can be provided by applying the above-described coating material composition. The phosphor coating film 26 converts the light emitted from the light-emitting element into light of another wavelength or color temperature.

The coating method is not particularly limited. A preferred method is a printing method such as a screen printing method. In the present embodiment, by setting the viscosity of the coating material composition to be equal to or more than 60 dPa·s and equal to or less than 450 dPa·s, a uniform phosphor coating film 26 having an appropriate thickness can be provided in application of the screen printing method. Needless to say, the coating method may be another method, and for example, the coating material composition may be applied using various coaters known in the field of coating material.

It is preferable to perform a drying treatment or a curing treatment after the coating. Conditions for the drying treatment are, for example, equal to or higher than 60° C. and equal to or lower than 100° C. for equal to or more than 15 minutes and equal to or less than 60 minutes. Conditions for the curing treatment are, for example, equal to or higher than 100° C. and equal to or lower than 200° C. for equal to or more than 30 minutes and equal to or less than 240 minutes.

A coating amount of the coating material composition is adjusted so that the thickness of the phosphor coating film 26 in the illumination device as a final product is preferably equal to or less than 150 μm, more preferably equal to or more than 30 μm and equal to or less than 100 μm, and still more preferably equal to or more than 30 μm and equal to or less than 80 μm.

By setting the content of the phosphor particles in the coating material composition to be equal to or more than 25 vol %, preferably equal to or more than 30 vol % and more preferably equal to or more than 35 vol %, even in a case where the thickness of the phosphor coating film 26 is equal to or less than 150 μm, the light emitted from the surface-mounted LED element 28 can be sufficiently converted into fluorescent light, and the light emitted from the surface-mounted LED element 28 does not easily pass through the phosphor layer.

Incidentally, the cured white layer 24 and/or the phosphor coating film 26 may be mechanically drilled to provide holes through which the solder 30 passes. For the subsequent connection between the surface-mounted LED element 28 (light-emitting element) and the first copper foil 22 with the solder 30, a known method can be appropriately applied.

Examples of the surface-mounted LED element 28 (light-emitting element) include CSP, a surface mount device (SMD), and a flip-chip element. In the present embodiment, the light-emitting element is preferably CSP. In addition, the light-emitting element normally emits blue light.

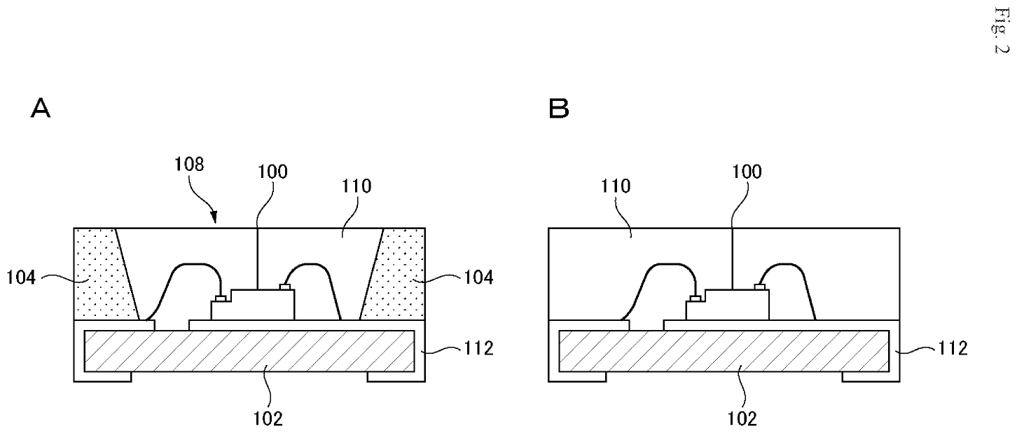

In the present embodiment, it is particularly preferable that the light-emitting element does not include a reflector. Specifically, as shown in FIG. 2A, in a known surface-mounted LED element (light-emitting element), a reflector is included, and light from the LED chip does not leak laterally or downwardly. However, in the present embodiment, as shown in FIG. 2B, it is preferable that the surface-mounted LED element 28 (light-emitting element) does not include a reflector.

By using a light-emitting element which does not include a reflector, light from the LED chip leaks laterally or downwardly. The leaked light hits a portion indicated by a of the phosphor coating film 26, and the portion a emits light. As a result, problems of glare and multiple shadows are further reduced.

In the light-emitting element of FIG. 2A, a semiconductor light-emitting element 100 is disposed in a package-like portion 108 formed by a substrate 102 and a reflector (housing) 104, and the package-like portion 108 is filled with a sealing member 110 (light-transmitting resin). The substrate 102 can include a wiring 112.

In FIG. 2B, the same elements as in FIG. 2A are labeled with the same reference numerals. The housing (reflector) is not used in the light-emitting element of FIG. 2B. After mounting the semiconductor light-emitting element 100 as illustrated, the sealing member 110 can be formed by molding using a desired mold. Alternatively, the sealing member 110 molded in a desired shape may be prepared in advance and adhered to the substrate 102 so as to cover the semiconductor light-emitting element 100.

The embodiments of the present invention have been described above, but these are examples of the present invention and various configurations other than the above can be adopted. In addition, the present invention is not limited to the above-described embodiments, and modifications, improvements, and the like within the range in which the object of the present invention can be achieved are included in the present invention.

### EXAMPLES

Embodiments of the present invention will be described in detail based on Examples and Comparative Examples. It should be noted that the present invention is not limited to Examples only.

<Material>

The followings were prepared.

(Phosphor Particles)
CASN-1: CASN-based phosphor substance manufactured by Denka Company Limited, product number: RE-650YMDB, D₅₀=15.7 μm
CASN-2: CASN-based phosphor substance manufactured by Denka Company Limited, product number: RE-Sample 650SD4, D₅₀=3.2 μm
YAG phosphor substance (used in Comparative Example 2): D₅₀=8.5 μm

A particle size distribution (D₅₀) of the phosphor particles was measured as follows.

(1) Dispersion Treatment Using Ultrasonic Waves

A dispersion liquid in which 30 mg of phosphor particles was uniformly dispersed in 100 mL of a sodium hexametaphosphate aqueous solution adjusted to 0.2% by mass was charged into a cylindrical container with a bottom radius of 2.75 cm. A cylindrical tip with a radius of 10 mm of an ultrasonic homogenizer (manufactured by NISSEI Corporation, US-150E) was immersed in the dispersion liquid for 1.0 cm or more, and was irradiated with ultrasonic waves at a frequency of 19.5 kHz and an output of 150 W for 3 minutes.

(2) Measurement of Particle Size Distribution

The dispersion liquid prepared as in (1) above was measured using a laser diffraction and scattering particle size distribution analyzer (manufactured by MicrotracBEL Corp., MT3300EXII) to obtain a particle size distribution. In addition, D₅n was obtained from data of the particle size distribution.

(Curable Resin Component)

Silicone resin “RSN-0805” of Dow Toray Co., Ltd. (containing silanol group, silanol content (OH weight): 1%, silicon dioxide content: 48% by weight, phenyl:methyl ratio=1.1:1, weight-average molecular weight: 200×10³ to 300×10³, containing xylene, resin solid content: 50% by weight)

(Fluidity Modifier)

Fumed silica AEROSIL 200 of NIPPON AEROSIL CO., LTD.

(Solvent)

Butyl Carbitol

<Preparation of Coating Material Composition>

Among components described in the table below, first, a curable resin component (silicone resin) and a solvent were mixed to obtain a uniform solution.

Thereafter, phosphor particles and a fluidity modifier (only in Example 3) were added to the solution, and uniformly mixed and dispersed to obtain a coating material composition.

A viscosity of the obtained coating material composition was measured under conditions of 25° C. and a rotation speed of 20 rpm using a No. 4 rotor of a B-type viscometer.

<Formation of Coating Film (Phosphor Layer) and Production of Illumination Device>

Using the coating material composition and the like prepared above, an illumination device having the structure described in FIG. 1 (a plurality of CSPs arranged on the phosphor layer at regular intervals) was produced. A production procedure is briefly described below.
(1) As a material for the insulating substrate, a bonding sheet CS-3305A manufactured by RISHO KOGYO CO., LTD., in which copper foils were laminated on both surfaces, was prepared. This copper foil was etched to form a copper circuit on the first copper foil.
(2) A white layer having a thickness of 40 μm was formed on the first copper foil using a white coating material (a product obtained by kneading titanium oxide/alumina with a silicone binder at 50 vol %).
(3) On the white layer, the above-described phosphor coating material was printed (film-formed) by a screen printing method using a screen with a mesh number of 86, pre-cured at 80° C. for 30 minutes, and post-cured (main-cured) at 180° C. for 60 minutes. As a result, a phosphor layer was formed. A thickness of the phosphor layer in this case was 50 μm.
(4) Holes for soldering were provided by drilling a part of the white layer and the phosphor layer. A commercially available CSP (WICOP SZ8-Y15-WW-C8, manufactured by Seoul Semiconductor Co., Ltd., product without reflector, color temperature: 2200 to 2300 K), which was the surface-mounted LED element, and the first copper foil (copper circuit) were electrically connected with the solder.

<Evaluation: Printability>

In the above (3),
a case where the printed phosphor coating material did not flow before the pre-curing and a uniform phosphor layer having a film thickness of 45 to 55 μm could be formed was evaluated as good printability (o),
a case where the printed phosphor coating material flowed slightly before the pre-curing but a uniform phosphor layer having a film thickness of 45 to 55 μm could be formed was evaluated as normal printability (Δ), and
a case where a phosphor layer having a sufficient film thickness could not be formed or unevenness occurred in the film was evaluated as poor printability (X).

<Evaluation: Appearance of Phosphor Layer>

An appearance of the phosphor layer formed in the above (3) was observed. In Table 2 below, a case where no abnormality which could cause a practical problem was found was described as “No abnormality”, and a case where an abnormality which could cause a practical problem was found was described as a detail of the abnormality.

<Evaluation: Durability and the Like of Phosphor Layer>

For those that were “No abnormality” in the evaluation of appearance of the phosphor layer described above, test for the items in Table 1 below were performed. Those that satisfied the acceptance criteria for all the items in Table 1 were described as “Accepted” in Table 2.

TABLE 1

| Item | Method | Acceptance Criteria |
|---|---|---|
| Adhesiveness | Using sharp cutter, drawing 100 base | No peeling |
| | eyes 1 mm apart that reach insulating | |
| | substrate, and attaching cellophane | |
| | tape to surface and peeling off at once | |
| Hardness | Compliance with JIS K5600-5-4 | 3H |
| Solvent resistance | After immersing in isopropyl alcohol at | No abnormality such |
| | room temperature for 5 minutes, attaching | as swelling or |
| | cellophane tape and peeling off at once | peeling of coating |
| | | film |
| Acid resistance | After immersing in 10% sulfuric acid at | No abnormality such |
| | room temperature for 30 minutes, attaching | as swelling or |
| | cellophane tape and peeling off at once | peeling of coating |
| | | film |
| Alkali resistance | After immersing in 5% sodium hydroxide | No abnormality such |
| | at room temperature for 5 minutes, | as swelling or |
| | attaching cellophane tape and peeling | peeling of coating |
| | off at once | film |
| Solder heat resistance | After immersing in solder bath at 260° C. | No abnormality such |
| | for 20 seconds, check appearance of | as swelling or |
| | coating film | peeling of coating |
| | | film |
| Pressure cooker test | After aging at temperature of 121° C. and | No abnormality such |
| (PCT) | pressure of 0.2 MPa for 9 hours, | as swelling or |
| | attaching cellophane tape and peeling off | peeling of coating |
| | at once | film |
| Cooling and heating | After 1000 cooling and heating cycles | No peeling |
| cycle | with 1 cycle of (−40° C. for 30 minutes → | |
| | 125° C. for 30 minutes), performing | |
| | above-described evaluation of | |
| | “Adhesiveness” | |
| Heat resistance | After aging at 150° C. for 1000 hours, | No peeling |
| | performing above-described evaluation | |
| | of “Adhesiveness” | |

<Evaluation: Conversion of Color Temperature>

A current was passed through the illumination device produced as described above to cause the illumination device to emit light.

A color temperature of the light emitted from the illumination device was measured using a total luminous flux measurement system (equipped with an integrating sphere) manufactured by OTSUKA ELECTRONICS CO., LTD. The measured color temperature was 2000 to 2100 K, and in a case where a color temperature of CSP itself (2200 to 2300 K) was converted by at least 100 K or more, conversion property of the color temperature was evaluated as good (O). On the other hand, the measured color temperature was 2100 to 2200 K, and in a case where conversion of the color temperature remained within 100 K, conversion property of the color temperature was evaluated as insufficient (X).

In Comparative Example 2 in which properties of the phosphor layer were abnormal, this evaluation was not performed.

Composition and evaluation results of the phosphor coating material are summarized in the table below.

TABLE 2

| | | | | | Comparative | Comparative |
|---|---|---|---|---|---|---|
| | Example 1 | Example 2 | Example 3 | Example 4 | Example 1 | Example 2 |
| Phosphor particles | 50 vol % in all | — | 48.1 vol % in all | 35 vol % in all | 20 vol % in all | 50 vol % in all |
| CASN-1 (large particle | non-volatile | | non-volatile | non-volatile | non-volatile | non-volatile |
| size: D₅₀ = 16 μm) | components | | components | components | components | components |
| | | | | | | (where, YAG phosphor |
| | | | | | | substance) |
| Phosphor particles | — | 50 vol % in all | 12.0 vol % in all | — | — | — |
| CASN-2 (small particle | | non-volatile | non-volatile | | | |
| size: D₅₀ = 5 μm) | | components | components | | | |
| Curable resin component | 50 vol % in all | 50 vol % in all | 38.8 vol % in all | 50 vol % in all | 80 vol % in all | 20 vol % in all |
| Silicone resin | non-volatile | non-volatile | non-volatile | non-volatile | non-volatile | non-volatile |
| | components | components | components | components | components | components |
| Fluidity modifier | — | — | 0.84 parts by mass | — | — | — |
| | | | with respect to 100 | | | |
| | | | parts by mass of | | | |
| | | | phosphor particles | | | |
| | | | and curable resin | | | |
| | | | component | | | |
| Solvent | 20 parts by mass | 20 parts by mass | 14 parts by mass | 20 parts by mass | 20 parts by mass | 10.5 parts by mass |
| | with respect to | with respect to | with respect to | with respect to | with respect to | with respect to |
| | 100 parts by mass | 100 parts by mass | 100 parts by mass of | 100 parts by mass | 100 parts by mass | 100 parts by mass |
| | of all non-volatile | of all non-volatile | phosphor particles | of all non-volatile | of all non-volatile | of all non-volatile |
| | components | components | and curable resin | components | components | components |
| | | | component | | | |
| Viscosity (dPa · s) | 100 | 300 | 150 | 80 | 50 | more than 500 |
| Evaluation: printability | ◯ | ◯ | ◯ | Δ | X | X |
| | | | | | (difficult to | (occurrence of |
| | | | | | secure film | unevenness) |
| | | | | | thickness) | |
| Evaluation: durability | Accepted | Accepted | Accepted | Accepted | Accepted | Not accepted |
| of phosphor layer | | | | | | |
| Evaluation: device | ◯ | ◯ | ◯ | ◯ | X | Not evaluated |
| color temperature | | | | | | |

By using a phosphor coating material which contained the phosphor particles and the curable resin component and had a viscosity of equal to or more than 60 dPa·s and equal to or less than 450 dPa·s, measured at 25° C. and a rotation speed of 20 rpm using a B-type viscometer, a phosphor layer could be formed by processing at a relatively low temperature of approximately 180° C. without requiring sintering at a high temperature like a glass binder. In addition, the appearance and durability of the formed phosphor layer were good. Furthermore, by the formed phosphor layer, the color temperature of the light emitted from CSP was significantly converted.

Priority is claimed on Japanese Patent Application No. 2020-134392, filed Aug. 7, 2020, the disclosure of which is incorporated herein by reference.

### REFERENCE SIGNS LIST

20: insulating substrate
22: first copper foil
22B: second copper foil
24: white layer
26: phosphor coating film
28: surface-mounted LED element
30: solder
32: white layer (white resin layer)
100: semiconductor light-emitting element
102: substrate
104: reflector (housing)
108: package-like portion
110: sealing member
112: wiring

1. A phosphor coating material comprising:
phosphor particles; and
a curable resin component,
wherein a viscosity measured at 25° C. and a rotation speed of 20 rpm using a B-type viscometer is equal to or more than 60 dPa·s and equal to or less than 450 dPa·s.

2. The phosphor coating material according to claim 1,
wherein the curable resin component includes a thermosetting resin component.

3. The phosphor coating material according to claim 1,
wherein the curable resin component includes a silicone resin.

4. The phosphor coating material according to claim 1,
wherein the curable resin component includes a silicone resin having a phenyl group and a methyl group.

5. The phosphor coating material according to claim 1,
wherein the curable resin component includes a silicone resin having a silanol group.

6. The phosphor coating material according to claim 1,
wherein a median diameter D₅₀ of the phosphor particles is equal to or more than 1 μm and equal to or less than 20 μm.

7. The phosphor coating material according to claim 1,
wherein, in a particle size distribution curve of the phosphor particles, two or more maxima are observed.

8. The phosphor coating material according to claim 7,
wherein, in the particle size distribution curve of the phosphor particles, maxima are observed in both a region of a particle size of equal to or more than 1 μm and equal to or less than 6 μm and a region of a particle size of equal to or more than 10 μm and equal to or less than 25 μm.

9. The phosphor coating material according to claim 1,
wherein the phosphor particles include one or two or more kinds selected from the group consisting of a CASN-based phosphor substance, an SCASN-based phosphor substance, a La₃Si₆N₁₁-based phosphor substance, a Sr₂Si₅N₈-based phosphor substance, a Ba₂Si₅N₈-based phosphor substance, an α-sialon-based phosphor substance, a β-sialon-based phosphor substance, a LuAG-based phosphor substance, and a YAG-based phosphor substance.

10. The phosphor coating material according to claim 1, further comprising:
a fluidity modifier.

11. The phosphor coating material according to claim 1, further comprising:
a solvent.

12. The phosphor coating material according to claim 11,
wherein the solvent includes an aromatic hydrocarbon solvent.

13. A coating film formed from the phosphor coating material according to claim 1.

14. The coating film according to claim 13,
wherein a thickness is equal to or less than 150 μm.

15. A phosphor board comprising:
the coating film according to claim 13.

16. An illumination device comprising:
an insulating substrate;
a coating film provided on one surface of the insulating substrate by the phosphor coating material according to claim 1; and
a light-emitting element installed on a surface of the coating film opposite to the insulating substrate.

17. The illumination device according to claim 16,
wherein a plurality of the light-emitting elements is installed.

18. The illumination device according to claim 16,
wherein the light-emitting element includes no reflector.
